(19) United States
(12) Patent Application Publication
(10) Pub. No.: US 2022/0197139 A1
(43) Pub. Date: Jun. 23, 2022

(54) PHOTORESIST COMPOSITION AND METHOD OF FABRICATING SEMICONDUCTOR DEVICE USING THE SAME

(71) Applicant: SK hynix Inc., Gyeonggi-do (KR)

(72) Inventors: Jae Hee SIM, Gyeonggi-do (KR); Ji Eun KIM, Gyeonggi-do (KR); Chung Hyeon BAN, Gyeonggi-do (KR)

(21) Appl. No.: 17/527,813

(22) Filed: Nov. 16, 2021

(30) Foreign Application Priority Data
Dec. 17, 2020 (KR) 10-2020-0177091

(51) Int. Cl. G03F 7/039; G03F 7/038; G03F 7/004

(52) U.S. Cl. CPC G03F 7/039; G03F 7/0045; G03F 7/038

(57) ABSTRACT

A photoresist composition contains: a polymer comprising a first compound and a second compound; a photoacid generator; and a solvent. The first compound has a unit structure, which includes: hydrogen or an alkyl group; and at least one of hydrogen, a hydroxyl group, an alkyl group, an heteroalkyl group, a cycloalkyl group, an heterocycloalkyl group, an aryl group, and an heteroaryl group. The second compound has a unit structure, which includes at least one of hydrogen, a hydroxyl group, an alkyl group, an heteroalkyl group, a cycloalkyl group, an heterocycloalkyl group, an aryl group, and an heteroaryl group.

### CROSS-REFERENCES TO RELATED APPLICATION

The present application claims priority under 35 U.S.C. § 119(a) to Korean patent application number 10-2020-0177091, filed on Dec. 17, 2020, in the Korean Intellectual Property Office, which is incorporated herein by reference in its entirety.

### BACKGROUND

### 1. Technical Field

The present invention relates to a photoresist composition and a method of fabricating a semiconductor device using the same and, more particularly, to a method of fabricating a semiconductor device using a photoresist composition capable of controlling diffuse reflection occurring in an underlying layer.

### 2. Related Art

In order to form various patterns which are included in a semiconductor device, a photo process employing a photoresist composition is utilized. For example, a photoresist layer pattern may be formed by dividing a photoresist layer into an exposed portion and a non-exposed portion through an exposure process and removing the exposed portion through a developing process. Thereafter, a desired pattern may be formed by patterning an underlying layer using the photoresist layer pattern as an etch mask.

### SUMMARY

A photoresist composition according to an embodiment of the present invention may contain: a polymer including a first compound having a unit structure represented by the following Formula 1 and a second compound having a unit structure represented by the following Formula 2; a photoacid generator; and a solvent:

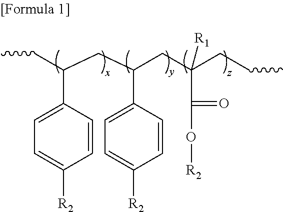

wherein: R₁ is hydrogen or an alkyl group having 1 to 8 carbon atoms; R₂s each independently include any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms; and x, y and z are molar fractions of repeating units constituting the first compound and satisfy the following conditions: x+y+z=1, 0<x/(x+y+z)<1, 0<y/(x+y+z)<1, and 0<z/(x+y+z)<1;

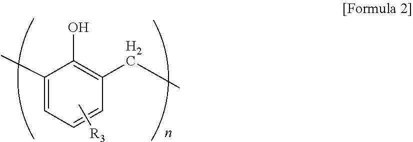

wherein R₃ includes any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms.

A method of fabricating a semiconductor device according to an embodiment of the present invention may include: providing a semiconductor substrate including an underlying layer having regions with different reflectivities that cause diffuse reflection; forming over the semiconductor substrate a photoresist layer including a photoresist composition containing: a polymer including a first compound having a unit structure represented by the following Formula 1 and a second compound having a unit structure represented by the following Formula 2; a photoacid generator; and a solvent; exposing the photoresist layer to light in a wavelength region of an i-line light source; developing the photoresist layer to form a photoresist layer pattern; and implanting ions into the underlying layer using the photoresist layer pattern as a mask:

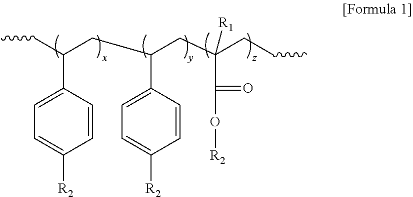

wherein: R₁ is hydrogen or an alkyl group having 1 to 8 carbon atoms; R₂s each independently include any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms; and x, y and z are molar fractions of repeating units constituting the first compound and satisfy the following conditions: x+y+z=1, 0<x/(x+y+z)<1, 0<y/(x+y+z)<1, and 0<z/(x+y+z)<1;

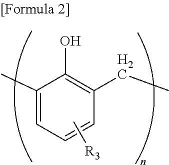

wherein R₃ includes any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms.

### BRIEF DESCRIPTION OF THE DRAWINGS

FIGS. 1A to 1D are sectional views showing each step of a method of fabricating a semiconductor device according to an embodiment of the present invention.

FIG. 2 is a graph showing the absorbance of a first compound and a second compound as a function of wavelength.

### DETAILED DESCRIPTION

The advantages and features of the present invention, and the way of attaining them, will become apparent with reference to the embodiments described below in conjunction with the accompanying drawings. However, the present invention is not limited to the embodiments disclosed below and may be embodied in a variety of different forms. Rather, these embodiments are provided to make this disclosure thorough and complete, and to fully convey the scope of the present disclosure to those skilled in the art, and the scope of the present invention should be defined only by the appended claim. In the drawings, the sizes and relative sizes of layers and regions may be exaggerated for clarity of illustration. Throughout the specification, like reference numerals refer to like elements.

A photoresist composition according to an embodiment of the present invention may contain: a polymer including a first compound having a unit structure represented by the following Formula 1 and a second compound having a unit structure represented by the following Formula 2; a photoacid generator; and a solvent:

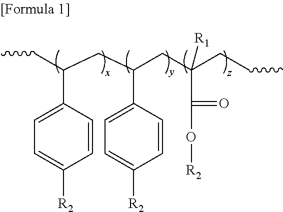

In Formula 1 above, R₁ may be hydrogen or an alkyl group having 1 to 8 carbon atoms.

R₂s may be each independently selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms. Each R₂ may be any one selected from the group consisting of the following formulas 1a to 1i and may determine the polarity of the entire exposure region:

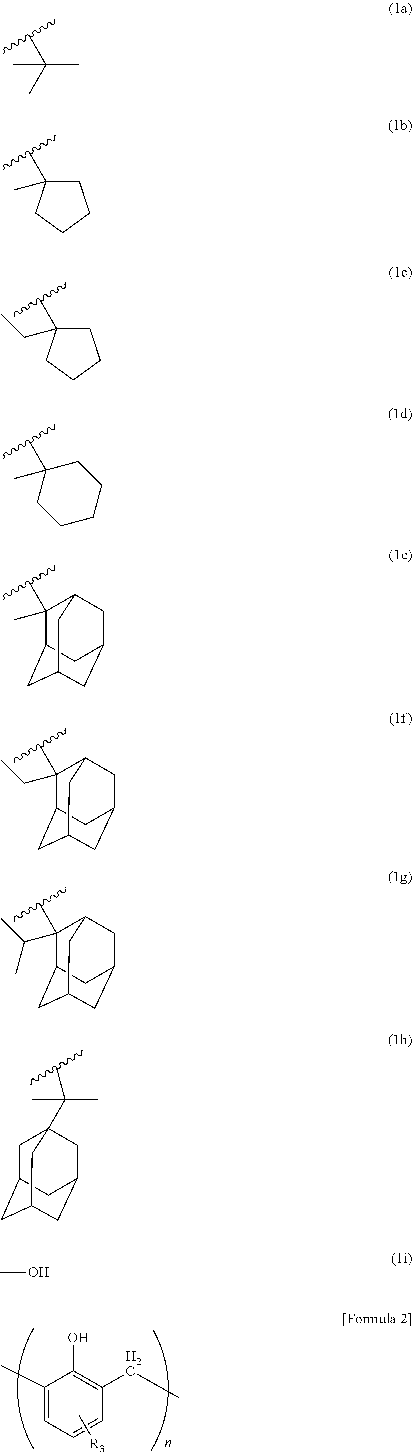

In Formula 2 above, R₃ may be any one selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms.

The photoacid generator (PAG) that is used in the present invention may be selected from among onium salts, including iodonium salts, sulfonium salts, phosphonium salts, diazonium salts or pyridinium salts, and imides.

An anionic moiety capable of acting as an acid after exposure is OSO₂CF₃, OSO₂C₄F₉, OSO₂C₈F₁₇, N(CF₃)₂, N(C₂F₅)₂, N(C₄F₉)₂, C(CF₃)₃, C(C₂F₅)₃, C(C₄F₉)₃, or a functional group represented by the following Formula 3:

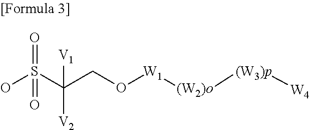

wherein V₁ and V₂ may be each independently a halogen; W₁ may be —(C═O)— or —(SO)₂—; W₂ may be an alkanediyl group having 1 to 10 carbon atoms; W₃ may be any one selected from the group consisting of a cycloalkyl group having 3 to 30 carbon atoms, an aryl group having 6 to 30 carbon atoms, an aralkyl group having 7 to 30 carbon atoms, an aryloxy group having 6 to 30 carbon atoms, an arylthio group having 6 to 30 carbon atoms, and an heterocyclic group having 5 to 30 carbon atoms; W₄ may be any one selected from the group consisting of hydrogen, a halogen group, a haloalkyl group having 1 to 10 carbon atoms, an alkylthio group having 1 to 10 carbon atoms, an aryl group having 6 to 30 carbon atoms, and combinations thereof; o is an integer ranging from 0 to 1; and p is an integer ranging from 0 to 2.

The photoacid generators as described above may be used alone or as a mixture of two or more. In addition, the photoacid generator may be contained in an amount of 0.3 to 15 parts by weight based on 100 parts by weight of the polymer solid content.

A uniform and flat photoresist film may be formed using a photoresist composition obtained by dissolving the polymer and the photoacid generator in a solvent having an appropriate evaporation rate and viscosity.

Examples of solvents that may be used in the present invention include esters such as ethylene glycol monomethyl ether, ethylene glycol monoethyl ether, ethylene glycol monopropyl ether, 2-methoxyethyl acetate, 2-methoxyethyl acetate, propylene glycol monomethyl ether acetate, propylene glycol monoethyl acetate, and propylene glycol monopropyl ether acetate; and ketones such as methyl isopropyl ketone, cyclohexanone, methyl 2-hydroxypropionate, ethyl 2-hydroxypropionate, 2-heptanone, ethyl lactate, and gamma-butyrolactone. These solvents may be used alone or as a mixture of two or more.

In addition, the amount of solvent used may be adjusted depending on the physical properties of the solvent, such as volatility and viscosity, so that a uniform photoresist layer may be formed.

The photoresist composition according to the present invention may further contain additives for the purpose of, for example, improving the applicability thereof.

Any suitable additives may be used without limitation as long as they are additives which are applied to conventional photoresist compositions. Specific examples of suitable additives include an alkali-solubility control agent, an acid diffusion control agent, and a surfactant, which may be used alone or as a mixture of two or more.

The alkali-solubility control agent may be any alkali-solubility control agent which is applied to conventional photoresist compositions, and specific examples thereof include phenols and carboxylic acid derivatives.

The acid diffusion control agent acts to control a diffusion phenomenon in which an acid generated from the photoacid generator by light irradiation is diffused into the photoresist layer, and to suppress a chemical reaction in an unexposed portion.

When this acid diffusion control agent is used, it is possible to improve the storage stability of the photoresist composition, and at the same time, further improve the resolution of photoresist, and suppress the linewidth of the photoresist layer pattern from being changed by a fluctuation in the time period from exposure to development (PED).

This acid diffusion control agent may be a basic compound. Specific examples of a suitable acid diffusion control agent include amines such as ammonia, methylamine, isopropylamine, n-hexylamine, cyclopentylamine, methylenediamine, ethylenediamine, dimethylamine, diisopropylamine, diethylenediamine, N,N-dimethylmethylenediamine, N,N-dimethylethylenediamine, trimethylamine, triethylamine, N,N,N′,N′-tetramethylmethylenediamine, N,N,N′,N′-tetramethylethylenediamine, N,N,N′,N′-tetramethyltetraethylenepentamine, dimethylethylamine, methylethylpropylamine, benzylamine, phenethylamine, benzyldimethylamine, tetramethyl ammonium hydroxide, aniline, N,N-dimethyltoluidine triphenylamine, phenylenediamine, pyrrole, oxazole, isoxazole, thiazole, isothiazole, imidazole, pyrazole, pyrroline, pyrrolidine, imidazoline derivatives, imidazolidine derivatives, pyridine derivatives, pyridazine derivatives, pyrimidine derivatives, pyrazine derivatives, pyrroline derivatives, pyrazolidine derivatives, piperidine derivatives, piperazine derivatives, and morpholine; nitrogen-containing compounds such as aminobenzoic acid, indolecarboxylic acid, amino acid derivatives (e.g., nicotinic acid, alanine, arginine, aspartic acid, etc.), 3-pyridinesulfonic acid, p-toluenesulfonic acid pyridinium, 2-hydroxypyridine, aminocresol, 2,4-quinolinediol, 2-(2-hydroxyethyl)pyridine, and 1-(2-hydroxyethyl)piperazine; amide derivatives such as formamide, N-methylformamide, N,N-dimethylformamide, acetamide, N-methylacetamide, N,N-dimethylacetamide, propionamide, and benzamide; or imide derivatives such as phthalimide, succinimide, and maleimide.

The acid diffusion control agent may be contained in an amount of 0.01 to 5 parts by weight based on 100 parts by weight of the polymer solid content. If the content of the acid diffusion control agent is less than 0.01 parts by weight, the influence of lag time after exposure may increase, thus adversely affecting the development of the pattern, and if the content is more than 5 parts by weight, the resolution and sensitivity may decrease.

The surfactant serves to improve the applicability and developability of the photoresist composition, and specific examples thereof include, but are not limited to, polyoxyethylene lauryl ether, polyoxyethylene stearyl ether, polyoxyethylene, and polyethylene glycol dilaurate.

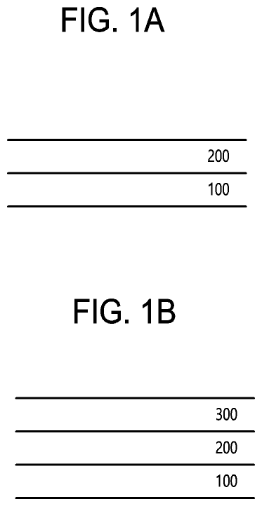

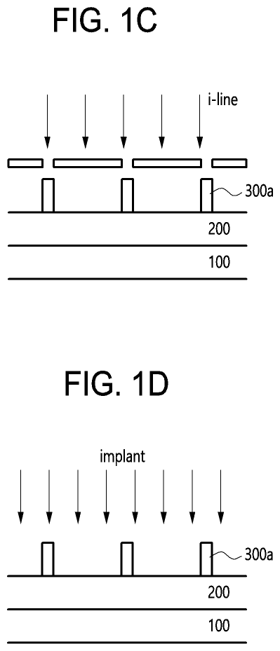

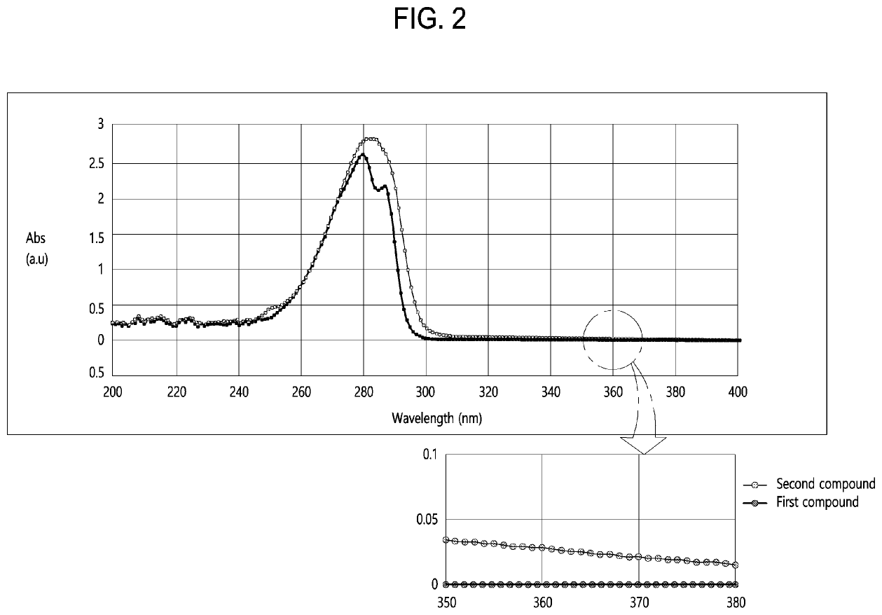

FIGS. 1A to 1D are sectional views showing each step of a method of fabricating a semiconductor device according to an embodiment of the present invention, and FIG. 2 is a graph showing the absorbance of the first compound and the second compound as a function of wavelength.

FIG. 1A is a sectional view of a semiconductor substrate 100 including an underlying layer 200 thereon. In this case, the underlying layer 200 may have regions with different reflectivities, because the regions have different doping ion concentrations and are implanted with different types of dopants. The different reflectivities of the regions may cause diffuse reflection during a subsequent exposure process.

FIG. 1B is a sectional view showing a photoresist layer 300 formed over the semiconductor substrate 100 including the underlying layer 200 thereon. Referring to FIG. 1B, a photoresist composition forming the photoresist layer 300 may contain: a polymer including a first compound having the unit structure represented by Formula 1 and a second compound having the unit structure represented by Formula 2; a photoacid generator; and a solvent. In an embodiment, the first compound is a polyhydroxystyrene (PHS) type compound, and the second compound is a novolac type compound. A novolac type compound means a low molecular weight polymer derived from a phenol and formaldehyde,

FIG. 1C is a sectional view showing a photoresist layer pattern 300a formed by exposing and developing the photoresist layer 300. Referring to FIG. 1C, for exposure of the photoresist layer 300 composed of the photoresist composition, an exposure process is performed using an i-line light source with a wavelength of 365 nm.

At this time, diffuse reflection may occur in the underlying layer 200 having regions with different reflectivities. Referring to FIG. 2, the second compound in the photoresist composition has a higher absorbance than the first compound in the wavelength region (365 nm) of the i-line light source. In the wavelength region of the i-line light source, the absorbance of the first compound is 0.002, and the absorbance of the second compound is 0.025, which is about 12 times higher than that of the first compound.

Thus, the photoresist composition containing the second compound may absorb diffuse reflection occurring in the underlying layer 200, thus reducing defects caused by the diffuse reflection in the exposure process and enabling a user to form a desired pattern. After exposing the photoresist layer 300, a photoresist layer pattern 300a may be formed by a developing process.

FIG. 1D is a sectional view showing a process of implanting ions into the semiconductor substrate 100 including the underlying layer 200 having the photoresist layer pattern 300a formed thereon. Referring to FIG. 1D, it can be seen that, since there is no underlying anti-reflective layer, it is possible to implant ions into the underlying layer 200 without a separate process of removing the underlying anti-reflective layer. It is possible to implant ions into the underlying layer 200 using the photoresist layer pattern 300a as a mask.

In a conventional art, an underlying anti-reflective layer is used to prevent diffuse reflection from occurring in the underlying layer 200. However, the underlying anti-reflective layer may prevent ions from flowing into the underlying layer 200 in an ion implantation process during a semiconductor fabrication process. Hence, in order to implant ions into the underlying layer 200 of the semiconductor substrate 100 having the underlying anti-reflective layer formed thereon, a separate etching process is additionally required to remove the underlying anti-reflective layer from a region into which ions are to be implanted. For this reason, a separate fabrication process step is required, and fabrication time and cost increase.

To overcome these disadvantages, the photoresist layer 300 formed of the photoresist composition according to an embodiment of the present invention may control diffuse reflection occurring in the underlying layer 200 without an underlying anti-reflective layer during the exposure process.

When the photoresist composition for a 365 nm (i-line) light source according to an embodiment of the present invention is used, it is possible to form a desired pattern by controlling diffuse reflection occurring in the underlying layer 200, and it is unnecessary to form the underlying anti-reflective layer, so that a separate etching process does not need to be added during an ion implantation process, thus reducing the number of fabrication processes, fabrication time and cost.

Although the present invention has been described with reference to the embodiments, those skilled in the art will appreciate that the present invention may be embodied in other specific forms without departing from the technical spirit or essential features of the present invention. Therefore, the embodiments described above are considered to be illustrative in all respects and not restrictive. Furthermore, the scope of the present invention is defined by the appended claims rather than the detailed description, and it should be understood that all modifications or variations derived from the meanings and scope of the claims and equivalents thereto are included within the scope of the present disclosure.

What is claimed is:

1. A photoresist composition containing:
a polymer comprising a first compound and a second compound;
a photoacid generator; and
a solvent,
wherein the first compound has a unit structure represented by Formula 1, 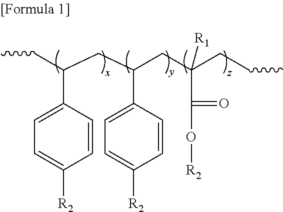
wherein,
R₁ is hydrogen or an alkyl group having 1 to 8 carbon atoms;
R₂s each independently comprise any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms; and
x, y and z are molar fractions of repeating units constituting the first compound and satisfy the following conditions: x+y+z=1, 0<x/(x+y+z)<1, 0<y/(x+y+z)<1, and 0<z/(x+y+z)<1; and
wherein the second compound has a unit structure represented by Formula 2, 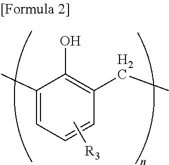
wherein,
R₃ comprises any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms.

2. The photoresist composition of claim 1, wherein the second compound is contained in an amount of 20 to 50 wt % based on a total weight of the photoresist composition.

3. The photoresist composition of claim 1, wherein an absorbance of the second compound in a wavelength region of an i-line light source is higher than that of the first compound.

4. The photoresist composition of claim 1, wherein the photoacid generator comprises any one selected from among onium salts, including iodonium salts, sulfonium salts, phosphonium salts, diazonium salts or pyridinium salts, and imides.

5. The photoresist composition of claim 1, wherein the photoacid generator is contained in an amount of 0.3 to 15 parts by weight based on 100 parts by weight of a solid content of the polymer.

6. The photoresist composition of claim 1, wherein the solvent comprises any one or more selected from among esters, including ethylene glycol monomethyl ether, ethylene glycol monoethyl ether, ethylene glycol monopropyl ether, 2-methoxyethyl acetate, 2-methoxyethyl acetate, propylene glycol monomethyl ether acetate, propylene glycol monoethyl acetate, and propylene glycol monopropyl ether acetate; methyl isopropyl ketone, cyclohexanone, methyl 2-hydroxypropionate, ethyl 2-hydroxypropionate, 2-heptanone, ethyl lactate, and gamma-butyrolactone.

7. The photoresist composition of claim 1, further containing at least one selected from among an alkali-solubility control agent, an acid diffusion control agent, and a surfactant.

8. The photoresist composition of claim 7, wherein the acid diffusion control agent is contained in an amount of 0.01 to 5 parts by weight based on 100 parts by weight of the solid content of the polymer.

9. A method of fabricating a semiconductor device, the method comprising:
providing a semiconductor substrate including an underlying layer having regions with different reflectivities that cause diffuse reflection;
forming over the semiconductor substrate a photoresist layer comprising a photoresist composition containing:
a polymer including a first compound and a second compound;
a photoacid generator; and
a solvent;
wherein the first compound has a unit structure represented by Formula 1, 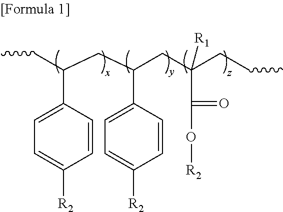
wherein:
R₁ is hydrogen or an alkyl group having 1 to 8 carbon atoms;
R₂s each independently comprise any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms; and
x, y and z are molar fractions of repeating units constituting the first compound and satisfy the following conditions: x+y+z=1, 0<x/(x+y+z)<1, 0<y/(x+y+z)<1, and 0<z/(x+y+z)<1; and
wherein the second compound has a unit structure represented by Formula 2, 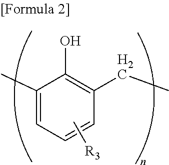
wherein R₃ comprises any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms;
exposing the photoresist layer to light in a wavelength region of an i-line light source;
developing the photoresist layer to form a photoresist layer pattern; and
implanting ions into the underlying layer using the photoresist layer pattern as a mask.

10. The method of claim 9, wherein the second compound represented by Formula 2 is contained in an amount of 20 to 50 wt % based on a total weight of the photoresist composition.

11. The method of claim 9, wherein an absorbance of the second compound in the wavelength region of the i-line light source is higher than that of the first compound.

12. The method of claim 9, wherein the photoacid generator comprises any one selected from among onium salts, including iodonium salts, sulfonium salts, phosphonium salts, diazonium salts or pyridinium salts, and imides.

13. The method of claim 9, wherein the photoacid generator is contained in an amount of 0.3 to 15 parts by weight based on 100 parts by weight of a solid content of the polymer.

14. The method of claim 9, wherein the solvent comprises any one or more selected from among esters, including ethylene glycol monomethyl ether, ethylene glycol monoethyl ether, ethylene glycol monopropyl ether, 2-methoxyethyl acetate, 2-methoxyethyl acetate, propylene glycol monomethyl ether acetate, propylene glycol monoethyl acetate, and propylene glycol monopropyl ether acetate; methyl isopropyl ketone, cyclohexanone, methyl 2-hydroxypropionate, ethyl 2-hydroxypropionate, 2-heptanone, ethyl lactate, and gamma-butyrolactone.

15. The method of claim 9, wherein the photoresist composition further contains at least one selected from among an alkali-solubility control agent, an acid diffusion control agent, and a surfactant.

16. The method of claim 15, wherein the acid diffusion control agent is contained in an amount of 0.01 to 5 parts by weight based on 100 parts by weight of the solid content of the polymer.

17. A photoresist composition containing:
a polymer comprising a first compound; and
a photoacid generator,
is wherein the first compound has a unit structure represented by Formula 1, 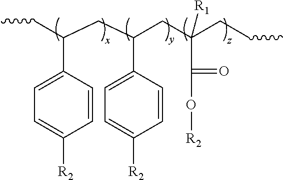
wherein,
R₁ is hydrogen or an alkyl group having 1 to 8 carbon atoms;
R₂s each independently comprise any one or more selected from the group consisting of hydrogen, a hydroxyl group, an alkyl group having 1 to 10 carbon atoms, an heteroalkyl group having 1 to 10 carbon atoms, a cycloalkyl group having 3 to 30 carbon atoms, an heterocycloalkyl group having 2 to 30 carbon atoms, an aryl group having 6 to 30 carbon atoms, and an heteroaryl group having 5 to 30 carbon atoms; and
x, y and z are molar fractions of repeating units constituting the first compound and satisfy the following conditions: x+y+z=1, 0<x/(x+y+z)<1, 0<y/(x+y+z)<1, and 0<z/(x+y+z)<1.
